(19) United States
(12) Patent Application Publication
(10) Pub. No.: US 2009/0105970 A1
(43) Pub. Date: Apr. 23, 2009

(54) SEMICONDUCTOR TESTER

(76) Inventors: Keisuke Kodera, Nara (JP); Masayuki Motohama, Kyoto (JP)

Correspondence Address: MCDERMOTT WILL & EMERY LLP, 600 13TH STREET, NW, WASHINGTON, DC, 20005-3096, US

(21) Appl. No.: 11/917,273

(22) PCT Filed: Jan. 29, 2007
(86) PCT No.: PCT/JP2007/051380

§ 371 Date: Dec. 12, 2007

(30) Foreign Application Priority Data
Apr. 4, 2006 (JP) 2006-103178

(51) Int. Cl. G01R 31/26

(52) U.S. Cl. 702/58

(57) ABSTRACT

In a calculator 520, a test bench 521 for event-driven asynchronous simulation described in an HDL is stored. An input-related description portion in the test bench 521 is input to an LSI tester 510 and converted into a signal input to a DUT 500, and then the signal input is applied to the DUT 500. Thereafter, an output signal produced from the DUT in response to the signal input is input to the LSI tester 510 and compared with an output signal obtained from a voltage condition table and the like, thereby determining the level of the output signal. This comparison result is input to the calculator 520, in which the comparison result is compared with an expected value and output waveform data described in the HDL test bench 521, so as to make a pass/failure determination for the DUT 500. It is thus possible to test the LSI (DUT) under the same conditions as the LSI is actually used in a product.

### TECHNICAL FIELD

The present invention relates to semiconductor testers, and particularly relates to a semiconductor tester capable of performing, in an easy manner, various kinds of tests, evaluations, and analyses that conventional testers found difficult to do, by combining a semiconductor device (which will be hereinafter referred to as an “LSI”) to be tested and data on simulation performed on a calculator in the design stage of the LSI.

### BACKGROUND ART

Miniaturization of LSI fabrication processes and design rules therefor has been advance year after year, which consequently produces effects such as faster operation and smaller area. In the recent development of LSIs, an increasing number of circuits are mounted to achieve higher performance, and LSIs are provided in the form of system on chip (which will be hereinafter referred to as an “SoC”) so as to have increased added value.

The number of circuits incorporated into an LSI called an SoC has been increasing year by year, and these circuits have various functions. In designing an LSI, asynchronous design is thus often performed. Such significant increase in the number of incorporated circuits produces the problem of increased power consumption, and asynchronous design is also widely performed in power-consumption-lowering techniques adopted to address the problem.

In performing a function test on an LSI incorporating such many asynchronous circuits, conventional testers with many restrictions have difficulty in fully realizing operations on various kinds of products into which the LSI to be tested will be incorporated.

A description will be made of a function test performed on an LSI by a conventional LSI tester.

An LSI tester applies an input signal to an LSI to be tested (which will be hereinafter referred to as a “DUT (Device Under Test)”) so as to make the DUT perform an intended operation. This input signal is obtained by applying 0/1 digital data stored in a pattern generator, in a waveform mode designated by a format controller in accordance with signal change timing specified by a timing generator under a voltage condition corresponding to 0/1 which is set to a voltage V and a current I.

And the LSI tester compares an output signal from the LSI to which the input signal was applied with a 0/1 expected value pattern stored in the pattern generator, thereby performing the function test on the DUT. In the test, a digital comparator determines whether or not the output signal from the DUT satisfies a 0/1 determination voltage condition, which is set in a VOH, at a strobe position specified by the timing generator.

The input signal and the expected value for the output are generated in accordance with a cycle-based test table called a test pattern (or a test vector). The test pattern during the test is usually stored in the pattern generator or in an accompanying pattern memory.

The conventional LSI tester is called a cycle-based test system, and various kinds of data for generating the input signal and the output expected value are defined in corresponding cycles (called test rates and timing sets).

Next, with reference to FIG. 1, a method for generating the test pattern will be described.

In LSI circuit design, a design method using a hardware description language (HDL), such as Verilog or VHDL, is widely adopted, and a method in which functional description data at register transfer levels at high abstraction levels (which will be hereinafter referred to as “RTL”) is converted to logic circuit data (which will be hereinafter referred to as a “netlist”) by using a logic synthesis technique is typically employed.

In typical test pattern generation, simulation data, which is used in logic verification of designed RTL and netlist, is used. In the simulation, data which is input to the designed circuit is used as an input signal for the test pattern, and an output from the designed circuit is captured as an expected value for the test pattern, thereby generating the test pattern.

Specifically, simulation results (e.g., VCD: Verilog Value Change Dump, in which simulation results in Verilog are dumped) are temporarily converted to a format, such as WGL (waveform generation language) or STIL (standard test interface language), and then converted to a test pattern format for the LSI tester.

However, a simulation typically performed in logic verification is event-driven in contrast to a cycle-based format such as the LSI tester. Thus, even if the conversion of the simulation results is made as described above, concepts of the LSI tester, such as a waveform mode and a test rate, are not reflected, and it is difficult to directly use the obtained test pattern format in the LSI tester. Therefore, many process steps are required to be performed, in which the simulation results are first converted to a cycle-based format, and the cycle-based format is converted to a WGL or STIL format, which is then converted to a test pattern format for the LSI tester.

In order to reduce such many process steps for the pattern generation, Patent Document 1 proposes an event type IC test system. Even in the proposed event type IC test system, however, a considerable number of process steps have to be performed so as to deal with data about simulation performed in the course of the development of a recent large-scale SoC as an event file. This is because the actual simulation environment for the large-scale SoC is not a test environment, in which the LSI is tested by an LSI tester, but an imitation (which will be hereinafter referred to as a “set environment”) of an environment in which the LSI is actually used.

For example, in a set environment shown in FIG. 2, suppose a specification in which a micro code is transmitted from an external flash memory 201, in which the micro code is stored, to an SRAM 202 in an SoC 200 through an external memory interface 204, and the SoC 200 operates in accordance with the micro code. In this specification, in a test environment, an event must be generated, in which the external flash memory 201 is deleted, and the micro code is input to the external memory interface 204. Also, in the test environment, in the case of a specification in which a work DRAM 203 is connected to the external memory interface 204, an event has to be generated in which data is passed to/from the DRAM 203.

It is of course possible to elaborate the event generation process itself so that the event file can be easily input to the event-type IC test system. Nevertheless, simulation data in the SoC design cannot be used directly.

### Patent Document 1: Japanese Laid-Open Publication No. 2005-525577

### DISCLOSURE OF THE INVENTION

### Problems that the Invention Intends to Solve

In testing an LSI incorporating numerous asynchronous circuits, the conventional LSI tester has great difficulty in achieving asynchronous operation and can only test the incorporated asynchronous circuits under conditions different from those in which the LSI is actually used in a product. Thus, a test other than the test using the LSI tester, for example, a BOST, which is perform in a different process step, is required, causing the test costs to form an increasing proportion of the LSI fabrication costs.

In addition, in the conventionally used LSI tester, a maximum operating frequency settable in the clock generator is defined. That is, clocks higher than the maximum operating frequency output from the clock generator cannot be applied, even if the maximum operating frequency of the DUT is higher than the maximum operating frequency output from the clock generator. In the test using the LSI tester, therefore, the maximum operating frequency cannot be ensured.

A problem arises in a case in which even with an LSI tester capable of outputting a high-speed clock of, e.g., 1 GHz, asynchronous operation is too complicated and complete reproduction thereof is difficult, such that the maximum operating frequency cannot be ensured. This is also true in a case where the maximum operating frequency of the DUT is lower than 1 GHz.

These problems occur due to the fact that the conventional LSI tester performs cycle-based operation using a test pattern.

As shown in FIG. 3(a), if all input signals are clocks which are one over a power of two with respect to the maximum operating frequency of the LSI tester, variation point timing is the same in each cycle, and each clock can be represented by the test pattern described above, thus causing no problems. And not only the clocks but also data inputs synchronized with the clocks can also be represented.

However, as shown in FIG. 3(b), in a case in which asynchronous clocks, which are not one over a power of two with respect to the maximum operating frequency of the LSI tester, are input, variation points of the input signals differ from cycle to cycle, making it difficult for a test pattern to represent the clocks.

Even with the conventional LSI tester, it is possible to change the timing in each cycle. Nevertheless, as a recent LSI incorporates numerous (more than 1000) pins, an enormous number of process steps are necessary to generate a test program, in which timings in all pins are taken into account.

As shown in FIG. 3(c), a solution to this may be to create a test pattern based on a cycle that matches the least common multiple frequency of all clock frequencies. In this case, however, problems occur in that the cycle may exceed the maximum operating frequency that the LSI tester can output, and the length of the test pattern is increased.

Furthermore, in an LSI such as an SoC, it is necessary to test many functions. Thus, the number of process steps for the generation of a test pattern for use in the test has been increased, and hence the entire LSI development costs have been increasing.

Simulation data which is used in the test pattern generation is data used in logic verification. Therefore, in the case of a circuit including many asynchronous circuits, input/output signals are naturally asynchronous. Generally, in simulations, an event-driven input pattern is used unlike a cycle-based pattern used in an LSI tester. If such event-driven asynchronous simulation data is directly converted to a test pattern, the resultant pattern will be a high-speed, large pattern as described above, which may not be usable in the LSI tester.

Therefore, aside from the logic verification, a cycle-based synchronous simulation for the test pattern generation has to be separately performed, resulting in an additional process step. In addition, the test pattern generated through such a cycle-based synchronous simulation is used in conditions different from the logic verification conditions and also different from conditions in which the LSI is actually used. The test pattern thus hardly reaches a level at which the product quality is sufficiently ensured.

As shown in FIG. 4, an object of the present invention is to provide an LSI tester which directly uses event-driven asynchronous simulation data used in logic verification so that a target LSI is tested under conditions closest to the actual use of the target LSI and the number of process steps for test pattern generation is reduced significantly, thereby achieving a high-quality test with a reduced number of process steps.

### Means for Solving the Problems

In order to achieve the object, according to the invention, an HDL test bench used in verification in the design stage of an LSI is directly used in testing a fabricated semiconductor device.

Specifically, an inventive semiconductor tester includes: a calculator in which an event-driven test bench, in which pieces of information on input timing, output timing, an input, and an expected value are described, and a voltage condition table, in which a power supply voltage and an input voltage are described, are recoded; and an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table, wherein the calculator receives a result of the comparison from the LSI tester through the interface circuit and compares the received comparison result with the expected value described in the event-driven test bench to determine whether the semiconductor device is a defective or a non-defective.

In the inventive semiconductor tester, the event-driven test bench is a VCD (Verilog Value Change Dump), which is output as a result of a logic simulation performed using the event-driven test bench.

In the inventive semiconductor tester, at least one or more external devices are connected to the semiconductor device; and the calculator determines whether the semiconductor device is a defective or a non-defective at the time of a system operation in which the semiconductor device and the external devices operate in conjunction with each other.

In the inventive semiconductor tester, the calculator includes at least one or more virtual devices which have to operate in conjunction with the semiconductor device; and the calculator determines whether the semiconductor device is a defective or a non-defective at the time of a system operation in which the semiconductor device and the virtual devices operate in conjunction with each other.

In the inventive semiconductor tester, at least one or more external devices are connected to the semiconductor device; the calculator includes at least one or more virtual devices which have to operate in conjunction with the semiconductor device; and the calculator determines whether the semiconductor device is a defective or a non-defective at the time of a system operation in which the semiconductor device and the external devices operate in conjunction with each other, and determines whether the semiconductor device is a defective or a non-defective at the time of a system operation in which the semiconductor device and the virtual devices operate in conjunction with each other.

In the inventive semiconductor tester, at least one or more external devices are connected to the semiconductor device; and the calculator determines whether the semiconductor device is a defective or a non-defective at the time of a system operation in which the semiconductor device and the external devices operate in conjunction with each other.

In the inventive semiconductor tester, the calculator includes at least one or more virtual devices which have to operate in conjunction with the semiconductor device; and the calculator determines whether the semiconductor device is a defective or a non-defective at the time of a system operation in which the semiconductor device and the virtual devices operate in conjunction with each other.

In the inventive semiconductor tester, at least one or more external devices are connected to the semiconductor device; the calculator includes at least one or more virtual devices which have to operate in conjunction with the semiconductor device; and the calculator determines whether the semiconductor device is a defective or a non-defective at the time of a system operation in which the semiconductor device and the external devices operate in conjunction with each other, and determines whether the semiconductor device is a defective or a non-defective at the time of a system operation in which the semiconductor device and the virtual devices operate in conjunction with each other.

In the inventive semiconductor tester, the calculator compares a result of a unit test or a system test on a defective semiconductor device in which a failure occurs with a result of a unit test or a system test on a non-defective semiconductor device in which no failure occurs, thereby specifying the location of a failure in the non-defective semiconductor device in accordance with information on the comparison.

In the inventive semiconductor tester, the calculator compares a result of a unit test or a system test on a defective semiconductor device in which a failure occurs with a result of a unit test or a system test on design data for a semiconductor device in which no failure occurs, thereby specifying the location of a failure in the non-defective semiconductor device in accordance with information on the comparison, the design data being recorded in the calculator.

In the inventive semiconductor tester, the calculator conducts a unit test or a system test on the defective semiconductor device, in which the location of the failure has been specified, and a unit test or a system test on design data for this semiconductor device, which is design data recorded in the calculator and reflecting failure information about the specified failure location, and compares results of the tests with each other to determine whether or not the failure information about the defective semiconductor device is correct.

In the inventive semiconductor tester, the calculator conducts a unit test or a system test on the defective semiconductor device, in which the location of the failure has been specified, and a unit test or a system test on design data for this semiconductor device, which is design data recorded in the calculator and reflecting failure information about the specified failure location, and compares results of the tests with each other to determine whether or not the failure information about the defective semiconductor device is correct.

In the inventive semiconductor tester, the calculator conducts a unit test or a system test on a semiconductor device processed by a focused ion beam system, and a unit test or a system test on a semiconductor device which is not processed by the focused ion beam system, and compares results of the tests with each other to determine whether or not the processing performed on the semiconductor device is successful processing.

In the inventive semiconductor tester, a unit test or a system test is conducted on a semiconductor device processed by a focused ion beam system, and a unit test or a system test is conducted on design data for this semiconductor device, and results of the tests are compared with each other to determine whether or not the processing performed on the semiconductor device is successful processing, the design data being recorded in the calculator.

As described above, according to the invention, an LSI-input-related description portion of the test bench for event-driven asynchronous simulation described in an HDL is input from the calculator to the LSI tester through the interface circuit and converted into a signal input to the DUT, and then the signal input is applied to the DUT, so that the HDL test bench used in verification in the design stage of the LSI is directly used to test the DUT. Thereafter, an output signal produced from the DUT in response to the signal input is input to the LSI tester and compared with an output signal obtained from the voltage condition table and the like so as to make a level determination. Through the interface circuit, this comparison result is input to the calculator, in which the comparison result is compared with the expected value and output waveform data described in the HDL test bench, thereby making a pass/failure determination for the semiconductor device to be tested. Since the test bench for event-driven asynchronous simulation described in an HDL is usable in its original format to test the LSI, it is possible to test the LSI under the same conditions as the LSI is actually used in a product, thereby achieving the high-quality test. In addition, the number of process steps for test pattern generation is reduced, whereby the number of process steps required for the development of the entire LSI is also reduced.

In particular, according to the invention, the DUT is tested with actual external devices, such as a microcomputer and a memory, connected with the DUT. The DUT is thus tested in a system in which the DUT, and the external devices based on specifications of a product, into which the LSI will be actually incorporated, operate in conjunction with each other, thereby enabling a function test on the LSI as a system in which data is passed to/from the external devices.

Also, according to the invention, the DUT is tested with virtual external device models in an environment described in an HDL connected with the DUT. It is thus possible to conduct performance evaluations on the DUT assuming a case in which quality variation or the like has occurred in the external devices that operate in conjunction with the DUT.

Furthermore, according to the invention, operation of a defective and operation performed in a case where a pseudo failure has been caused to occur in design data for that defective described in an HDL are compared and monitored, thereby easily specifying the location of a failure in the defective.

In addition, according to the invention, operation of an LSI subjected to FIB (processing by a focused ion beam system) and operation in HDL design data for that LSI to which the same modification has been made are compared and monitored, thereby easily determining whether or not the FIB processing on that LSI is successful processing.

### EFFECTS OF THE INVENTION

As described above, in the inventive semiconductor tester, since a test bench for event-driven asynchronous simulation described in an HDL is used in the original format thereof to test an LSI, the LSI is allowed to be tested under the same conditions as the LSI is actually used in a product, thereby achieving the high-quality test, while the number of process steps for test pattern generation is reduced, thereby producing the effect that the number of process steps required for the development of the entire LSI is also reduced.

In particular, according to the invention, not only a unit test on a DUT can be conducted, but also a test on a more complicated system, which includes operation performed in conjunction with external devices based on actual product specifications, can be carried out.

Furthermore, according to the invention, not only a unit test on a DUT can be performed, but also performance evaluations on the DUT can be conducted assuming a case in which quality variation or the like has occurred in external devices that operate in conjunction with the DUT.

Moreover, according to the invention, it is possible to analyze the location of a failure in an LSI under high-load conditions close to the actual operation.

In addition, according to the invention, in an LSI subjected to FIB (processing by a FIB system), it is possible to easily determine whether or not the FIB processing is successful processing.

### BRIEF DESCRIPTION OF DRAWINGS

FIG. 1 is a schematic diagram showing a conventional test pattern generation flow.

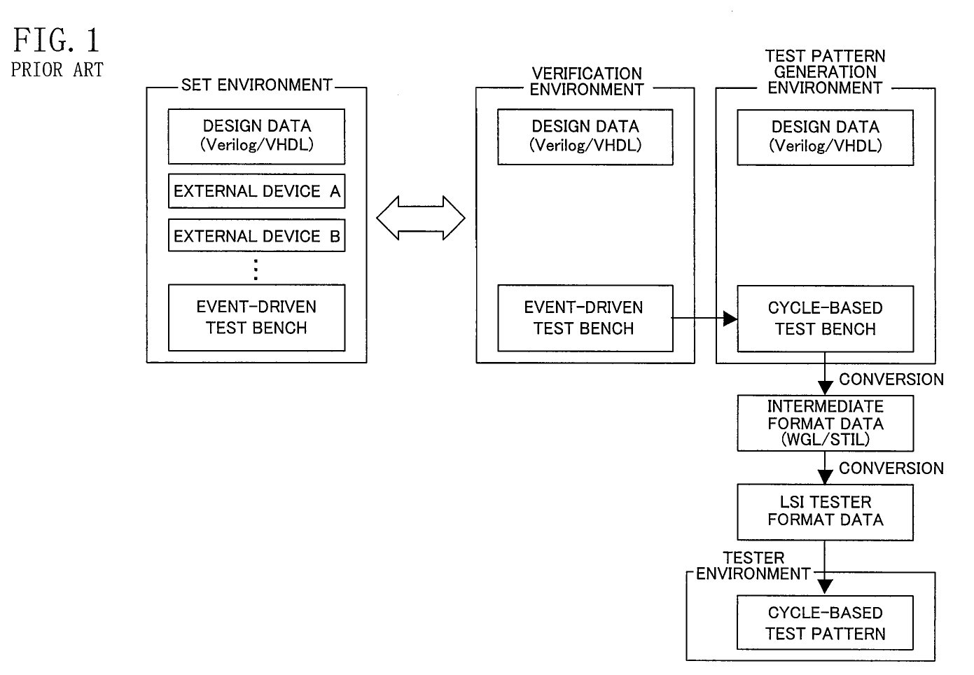

FIG. 2 is a schematic diagram showing an example of a product set incorporating an LSI.

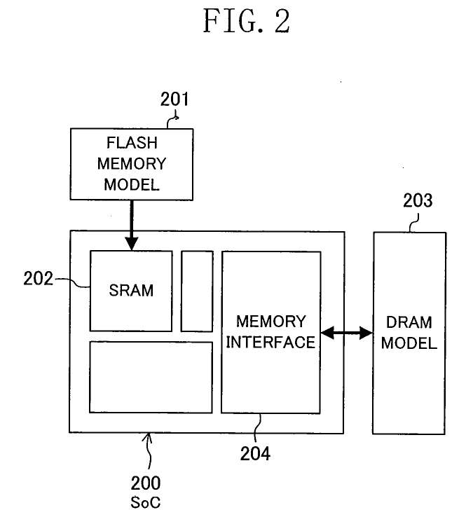

FIG. 3(a) is a schematic view for explaining a state in which three input signals maintain relationships of a power of two, FIG. 3(b) is a schematic view showing a state in which such relationships are not maintained, and FIG. 3(c) is a schematic view showing a test pattern cyclized so that the three input signals shown in FIG. 3(b) are represented by the single test cycle.

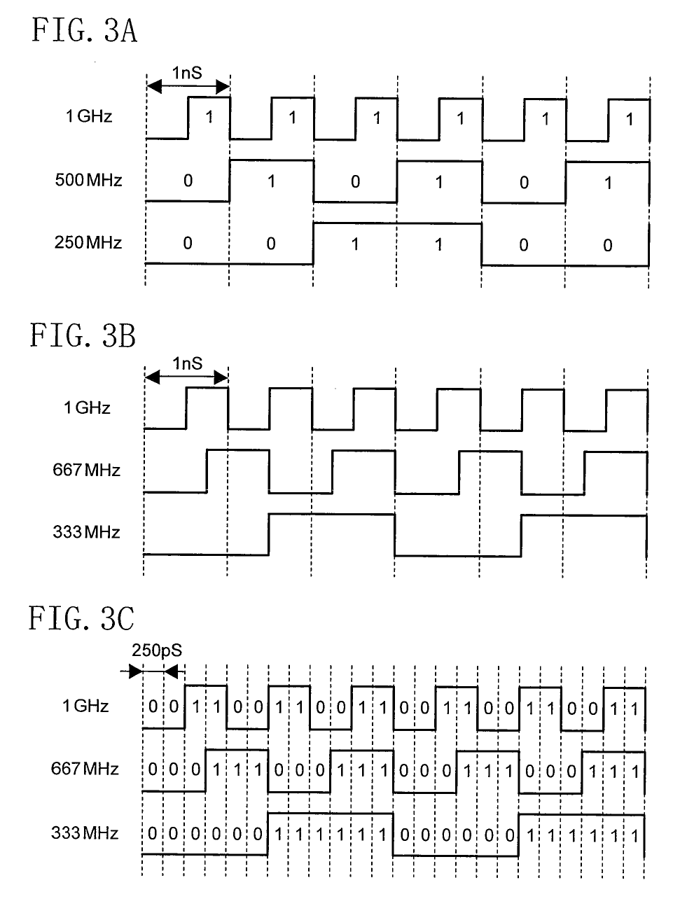

FIG. 4 is a view showing the concepts of the invention.

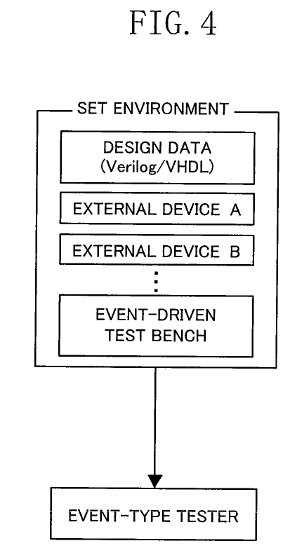

FIG. 5 is a block diagram illustrating the structure of a semiconductor tester according to a first embodiment of the invention.

FIG. 6 is a block diagram illustrating the structure of a semiconductor tester according to a second embodiment of the invention.

FIG. 7 is a block diagram illustrating the structure of a semiconductor tester according to a third embodiment of the invention.

FIG. 8 is a block diagram illustrating the structure of a semiconductor tester according to a fourth embodiment of the invention.

FIG. 9(a) is a schematic view showing estimation of the location of a failure in a defective, FIG. 9(b) is a schematic view showing estimation of the details of the failure in the defective, and FIG. 9(c) is a schematic view showing a determination as to whether or not FIB processing performed on a defective is success processing.

### EXPLANATION OF THE REFERENCE CHARACTERS

500 DUT (Semiconductor device to be tested)
510 LSI tester
511 Signal generator
512 Comparator
513 Pair including signal generator and comparator
520 Calculator
521 HDL test bench
522 Test condition table
600, 700, 800 DUT
601 External microcomputer (External device)
602, 802 External memory (External device)
610, 710, 810 LSI tester
620, 720, 820 Calculator
701, 803 Virtual microcomputer (Virtual device)
702 Virtual memory (Virtual device)
900 Non-defective LSI
901 Defective LSI
902 Design data
903 Design data containing a failure
904 LSI fabricated based on the failure-containing design data

### BEST MODE FOR CARRYING OUT THE INVENTION

Hereinafter, embodiments of the invention will be described with reference to the accompanying drawings.

### First Embodiment

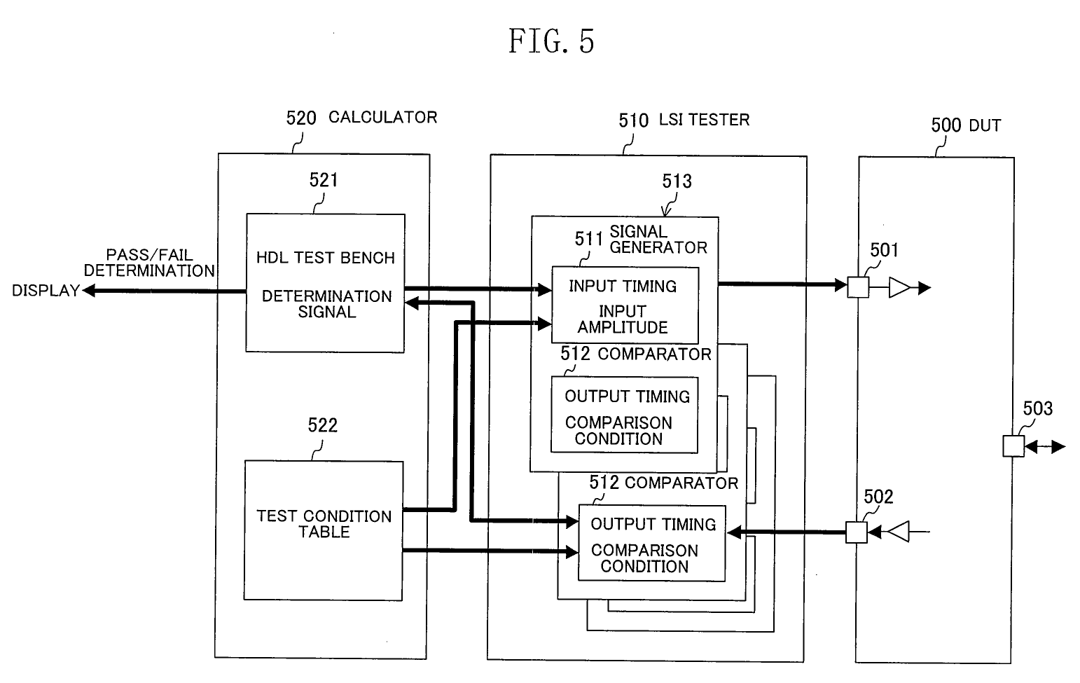

FIG. 5 shows the structure of a semiconductor tester according to a first embodiment of the invention.

In FIG. 5, the reference numeral 500 refers to a DUT to be tested, 510 to an LSI tester, and 520 to a calculator. The LSI tester 510 and the calculator 520 are connected by an interface hardware (an interface circuit (not shown)).

The DUT 500 has at least one or more pins. The DUT 500 shown in FIG. 5 has n terminals, and the first pin is an input terminal 501, the second pin is an output terminal 502, the third to (n−1)-th pins are omitted, and the n-th pin is an input/output terminal 503.

The LSI tester 510 has a pair 513, which includes a signal generator 511 and a comparator 512, for the terminal 1 pin of the DUT 500. The LSI tester 510 includes that number of such pairs 513 that corresponds to the total number of terminals of the DUT 500 or corresponds at least to the total number of terminals required to test the DUT 500.

The calculator 520 includes an HDL test bench 521 and a test condition table 522. The HDL test bench 521 was generated and used for function verification at the time of logic design. For an input signal, the HDL test bench 521 has information about input timing and data variation. For an output signal, the HDL test bench 521 has information about an expected value and output timing of the expected value comparison. The HDL test bench 521 is a VCD (Verilog Value Change Dump) which is output as a result of a logic simulation performed using an event-driven test bench.

The test condition table 522 has information about the voltage axes of the input signal and the output signal. For the input signal, a zero-level value (a voltage value at the time of “0”), a 1-level value (a voltage value at the time of “1”) or an input amplitude is defined, and for the output signal, an L threshold value (a value below this threshold value is L) and an H threshold value (a value above this threshold value is H) are defined. In performing a back annotation simulation, conditions such as determined temperature and test voltage are usable.

Next, with reference to FIG. 5, flows of signals from the start of a test to the end of the test will be described.

In the signal generator 511 that is connected with the input terminal 501 of the DUT through a pin electronics, input timing and data variations are determined from the HDL test bench 521, and an input amplitude is determined from the test condition table 522. The two pieces of information are put together to generate an input signal. This input signal is applied to the input terminal 501 of the first pin of the DUT through the pin electronics of the LSI tester 510.

Upon receipt of this input signal, the DUT 500 responds by producing an output signal from the output terminal 502 of the second pin through internal logic.

In the comparator 512 that is connected with the output terminal 502 of the DUT 500 through the pin electronics, the output signal of the DUT 500 is compared with the H threshold value and the L threshold value in the test condition table 522 simultaneously with the output timing of the expected value comparison produced from the HDL test bench 521. If the output signal is greater than the H threshold value, the comparator 512 determines that the output signal is H. If the output signal is smaller than the L threshold value, the comparator 512 determines that the output signal is L. If the output signal is between the L threshold value and the H threshold value, the comparator 512 determines that the output signal is an intermediate voltage Z. The calculator 520 compares the determination result output from the comparator 512 with the expected value in the HDL test bench 521. If the determination result and the expected value match, the calculator 520 makes a determination of PASS, and if not, the calculator 520 makes a determination of FAIL. The PASS/FAIL determination result is output to a file or is directly displayed on a display connected to the calculator 520, and then the test is terminated.

### Second Embodiment

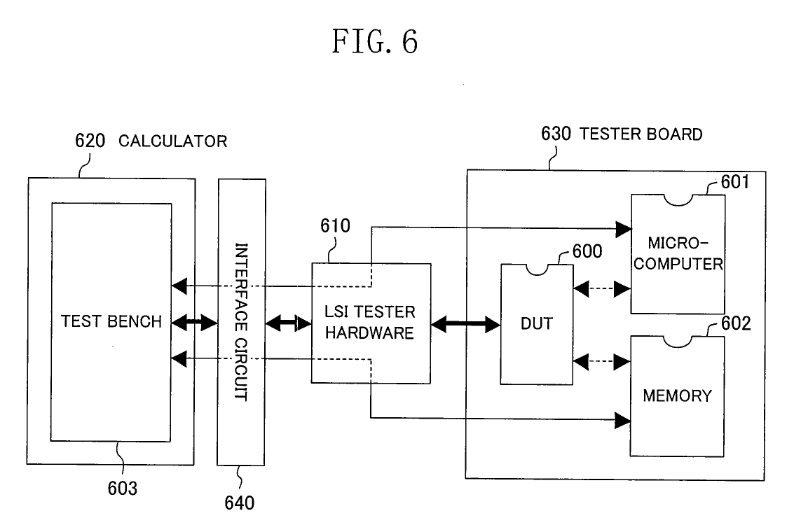

FIG. 6 shows the structure of a semiconductor tester according to a second embodiment of the invention.

This embodiment is characterized by having one or more externals devices other than a DUT 600 to be tested. As shown in FIG. 6, in this embodiment, these external devices are a microcomputer 601 and a memory 602, for example.

In a case in which an input signal needs to be directly applied to the external devices or an output signal needs to be compared with an expected value, that number of pairs (represented by the reference numeral 513 shown in FIG. 5), each including a signal generator and a comparator, that corresponds to the total number of terminals required to test the DUT 600 and the external devices has to be provided.

For instance, in the case of a system which uses the external microcomputer 601 and the external memory 602 (the external devices) in an actual product, a system test on the DUT 600 needs to be conducted, in which the DUT 600 is operated in conjunction with both the external microcomputer 601 and the external memory 602. In this example, the external devices are the external microcomputer 601 and the external memory 602. It is assumed that the data transfer rate of the external microcomputer 601 differs from that of the external memory 602, and that the external microcomputer 601 and the external memory 602 are asynchronous with each other.

After booted by the external microcomputer 601, the DUT 600 receives an input signal from an LSI tester 610, performs an operation using internal logic in the DUT 600, and writes the operation results in the external memory 602. Through the LSI tester 610, a calculator 620 reads the data written in the external memory 602 and compares the read data with an expected value to make a PASS/FAIL determination. By this test, the operation of the DUT 600 at the time of the data write to the external memory 602 is ensured.

On the other hand, the calculator 620 writes data in the external memory 602 in advance. After booted by the external microcomputer 601, the DUT 600 reads the data in the external memory 602 and performs an operation using internal logic. The calculator 620 reads the operation results through the LSI tester 610 to make a PASS/FAIL determination. By this test, the operation of the DUT 600 at the time of the data read from the external memory 602 is ensured.

With the one or more external devices, more complicated function tests closer to the actual use, like the two tests provided by way of example, can be performed.

A test using a conventional BOST (Built Out Self Test) requires an external device, such as a FPGA, in which a logic circuit is written to implement the test, and a nonvolatile memory, such as a ROM or a flash memory, in which a test program is written. And to prepare the test, the program has to be written in the ROM, the flash memory, or the like at least before the test. If the test program needs to be changed frequently for evaluations or tests, the memory has to be removed each time and the test program has to be rewritten in an environment in which the test program is written in the memory. Alternatively, it is necessary to prepare the required number of memories to perform the test. However, in this embodiment, first of all, the memory 602 does not have to be nonvolatile, and it is thus possible to write a desired test program in the memory 602 as needed before or during a test. Therefore, unlike the conventional test, for which multiple BOST devices or nonvolatile memories, in which test programs are written, must be prepared, only a combination of a minimum number of components is necessary to form the test device.

### Third Embodiment

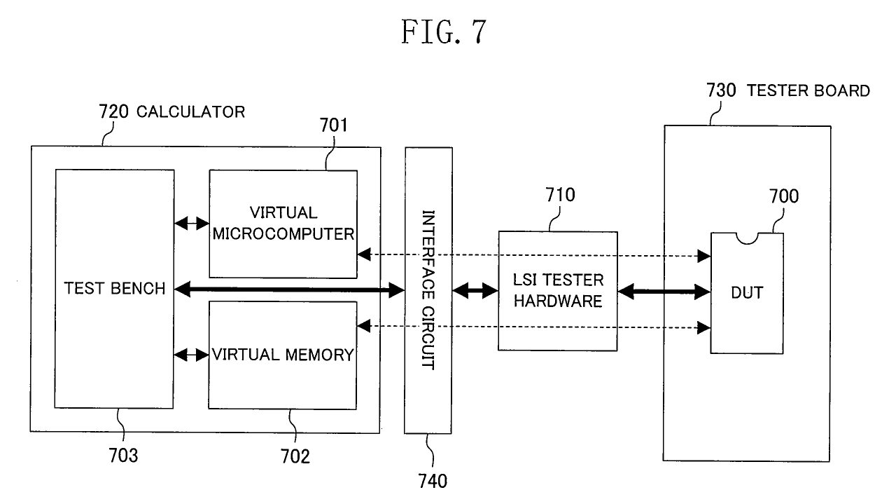

FIG. 7 shows the structure of a semiconductor tester according to a third embodiment of the invention.

This embodiment is characterized by having one or more virtual devices in a calculator 720. In FIG. 7, these virtual devices are a virtual microcomputer 701 and a virtual memory 702, for example.

In this embodiment, in testing a DUT 700, operation performed in conjunction with the virtual devices 701 and 702, which are not yet commercialized at the time of the design stage, can be tested. Also, if a failure is caused to occur in a pseudo manner in a specific part of virtual devices which are already commercialized, or if a parameter in the fabrication process is added to the virtual devices, performance evaluations on the DUT 700 can be conducted assuming a case in which quality variation has occurred not in the DUT 700 but in the external devices 701 and 702 that operate in conjunction with the DUT 700. In the case of operation performed in conjunction with general-purpose devices, such as the memory device 702, which are provided from multiple manufacturers, even if these devices subtly differ in performance and characteristics from one manufacturer to another, it is possible to easily conduct a test tailored to each device.

Furthermore, conventionally, a test has been performed by unilaterally applying an input signal from an LSI tester 710 to the DUT 700. In a case for example in which the DUT 700 does not assert an input signal unless the input signal was applied to the DUT 700 in response to a request output signal from the DUT 700, if the virtual microcomputer 711 produces, in response to the request signal from the DUT 700, data and input timing which are necessary for control of the DUT 700, a function test closer to the actual functions can be realized.

### Fourth Embodiment

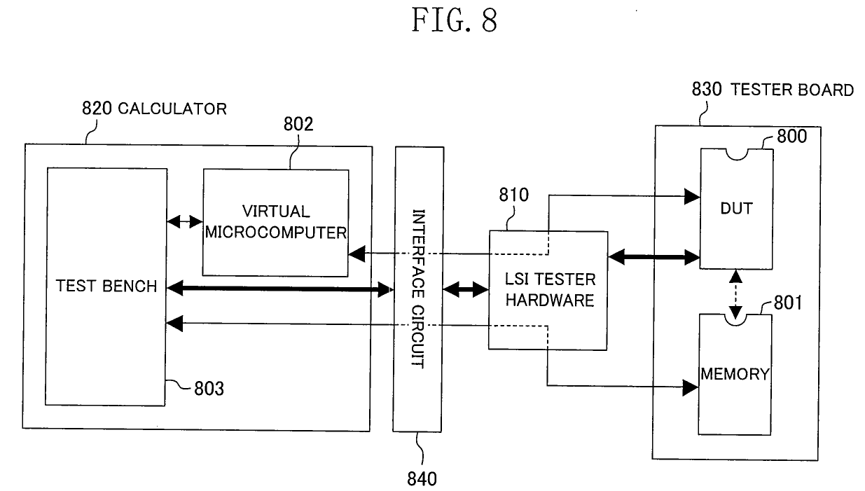

FIG. 8 shows the structure of a semiconductor tester according to a fourth embodiment of the invention.

This embodiment is characterized in that one or more externals devices are provided other than a DUT, and one or more virtual devices are provided in a calculator.

As already described in the second and third embodiments, in testing a DUT 800, if an already-commercialized external device (a memory in FIG. 8) 801 is connected, and a virtual microcomputer 802, serving as a virtual device which is not yet commercialized, is provided in a calculator 820, it becomes possible to conduct function evaluations on the entire system without waiting for the commercialization of the virtual device 802 that is to be commercialized.

Moreover, in a case, such as a BOST, in which many devices and components need to be mounted on a board, the problem of mounting many devices and components is avoidable by the combined use of the external device 801 other than the DUT 800 and the virtual device 802 in the calculator. And in a case in which it is difficult to physically mount the external device 801 on a jig (which will be hereinafter referred to as a “tester board”) 830 that connects the DUT 800 and an LSI tester 810, or in a case in which it is desired that effects of electromagnetic waves be reduced, these problems are avoidable by the use of the virtual device 802. Moreover, the effective use of the virtual device 802 also offers the advantage that the costs of generating the tester board 830 is reduced.

### Fifth Embodiment

Next, a semiconductor tester according to a fifth embodiment will be described.

When an LSI incorporated in an actual product is determined to be a defective because of a failure occurring in operation of the LSI, a failure analysis must be carried out. Nevertheless, some type of failure, by which the LSI is determined to be defective, cannot be made to reoccur just by performing a specific function test using the conventional cycle-based LSI tester, and such a failure only occurs under high-load conditions closer to the actual operation in which the LSI is made to perform multiples functions. In this embodiment, the first to fourth embodiments are used to conduct a test under high-load conditions closer to the actual operation, thereby easily enabling a failure to reoccur.

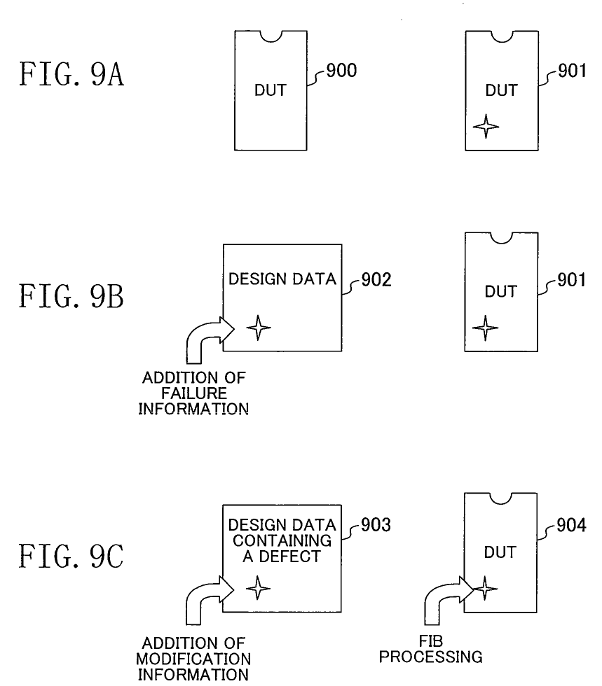

As shown in FIG. 9(a), a test is conducted on a defective 901 and on a non-defective 900, and the defective 901 fails the test. A terminal, through which the test results are output or some kind of response is output depending on the internal state during the execution of the test, is monitored, and in a case where an internal memory after the execution of the test, or a circuit or a device for storing the internal state is provided, the internal state is read and the results of the tests on the defective 901 and the non-defective 900 are compared, thereby estimating the location of the failure in the defective 901.

Also, as shown in FIG. 9(b), for the estimated failure location in the defective 901 specified by the above-described failure analysis, a pseudo failure, such as 0/1 fix, a short, or an open, is artificially caused to occur on design data 902, upon which the defective 901 DUT is based, in accordance with the failure, such as 0/1 degeneracy or a broken wire. A test, which the defective 901 will fail, is conducted on the defective 901 and on the design data 902 to which the failure information has been added. The results of the tests on the defective 901 and the design data 902 are compared. If the test results match, it is found that the failure details added to the design data 902 are correct, which allows the cause of the failure to be determined. This means that it is not necessary to open the defective 901 and physically analyze the failure details.

Therefore, in this embodiment, it is possible to conduct a failure analysis under high-load conditions close to the actual operation.

### Sixth Embodiment

Next, a semiconductor tester according to a sixth embodiment of the invention will be described.

This embodiment makes it possible to determine whether or not processing on an LSI performed using a FIB (a focused ion beam system) is successful processing, which will be described blow.

As shown in FIG. 9(c), it is assumed that, in the stage of evaluation of an LSI 904, a failure, which is not a problem in manufacturing, has been detected in design data 903 itself. Since the cost of modifying a mask required for the fabrication of the LSI 904 should be reduced as much as possible, usually, the design data is verified again, details of modification to be made are considered based on the reverification results, and then the package of the LSI 904 is opened so that processing by a FIB is performed according to the modification details. Thereafter, the LSI 904 subjected to the FIB processing is evaluated by an LSI tester or other evaluation device. If it is confirmed that no failure phenomenon occurs, the modification details are determined to be correct, and the mask is actually modified in accordance with the modification details. However, in a case where the processing by the FIB is failed processing, it is not possible to determine whether or not the modification details are correct.

The design data 903, in which the modification details have been reflected, and the LSI 904 after the FIB processing are subjected to a test at least including a test item in which the failure phenomenon reoccurs. From the test results, determinations are made as to the adequacy of the details of the FIB processing performed on the LSI (equivalent to the modification details reflected in the design data) and as to the success of the FIB processing. As a precondition, the design data prior to the modification and the LSI before the FIB processing need to pass all of the test items except for the item in which the failure phenomenon reoccurs. In addition, the design data 903 reflecting the modification details must pass the test item in which the failure phenomenon reoccurs.

Nevertheless, in a case in which it can be expected that an existing test item will not be passed due to the effects of the modification to the design data 903, the FAIL details of that test item are checked. And if FAIL details obtained when the post-FIB-processing LSI is subjected to that test differ from those checked in advance, the FIB processing is determined to be failed processing whether the post-FIB-processing LSI passes or fails that test.

It will be described below how to make the determinations as to the adequacy of the modification details and the success/failure of the FIB processing in accordance with the PASS/FAIL determination results of the test at least including the test item in which the failure phenomenon reoccurs. It is assumed that the modification does not affect the test items other than the test in which the failure phenomenon reoccurs.

The design data 903 and the post-FIB-processing LSI 904 are both tested for all items including the failure phenomenon item. If the design data 903 and the post-FIB-processing LSI 904 pass the test, it can be found that the modification details and FIB-processing details are both correct at least with respect to the failure phenomenon.

If the post-FIB-processing LSI 904 fails only the failure phenomenon item, it can be determined that the details of the modification to the design data 903 and the details of the FIB processing on the LSI 940 are not equivalent. This includes a case in which the FIB processing is failed processing.

If the post-FIB-processing LSI 904 passes none of the test items, it is of course determined that the FIB processing is failed processing.

If the design data 903 and the post-FIB-processing LSI 904 both pass the failure phenomenon item and fail a test item other than the failure phenomenon item, it is determined that although the failure phenomenon itself has been resolved by the modification details, another failure has occurred due to side effects or a failure hidden by the resolved failure has been found.

### INDUSTRIAL APPLICABILITY

As described above, according to the invention, event-driven asynchronous simulation data used in logic verification is directly used by an LSI tester, whereby a target semiconductor device is allowed to be tested under conditions close to the actual use and the number of process steps for test pattern generation is reduced significantly. The inventive LSI tester is thus applicable to a semiconductor tester which achieves a high-quality test with a reduced number of process steps.

1-14. (canceled)

15. A semiconductor tester comprising:
a calculator in which an event-driven test bench, in which pieces of information on input timing, output timing, an input, and an expected value are described, and a voltage condition table, in which a power supply voltage and an input voltage are described, are recoded; and
an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table,
wherein the calculator receives a result of the comparison from the LSI tester through the interface circuit and compares the received comparison result with the expected value described in the event-driven test bench to determine whether the semiconductor device is a defective or a non-defective;
at least one or more external devices are connected to the semiconductor device; and
the calculator determines whether the semiconductor device is a defective or a non-defective at the time of a system operation in which the semiconductor device and the external devices operate in conjunction with each other.

16. A semiconductor tester comprising:
a calculator in which an event-driven test bench, in which pieces of information on input timing, output timing, an input, and an expected value are described, and a voltage condition table, in which a power supply voltage and an input voltage are described, are recoded; and
an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table,
wherein the calculator receives a result of the comparison from the LSI tester through the interface circuit and compares the received comparison result with the expected value described in the event-driven test bench to determine whether the semiconductor device is a defective or a non-defective;
the calculator includes at least one or more virtual devices which have to operate in conjunction with the semiconductor device; and
the calculator determines whether the semiconductor device is a defective or a non-defective at the time of a system operation in which the semiconductor device and the virtual devices operate in conjunction with each other.

17. A semiconductor tester comprising:
a calculator in which an event-driven test bench, in which pieces of information on input timing, output timing, an input, and an expected value are described, and a voltage condition table, in which a power supply voltage and an input voltage are described, are recoded; and
an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table,
wherein the calculator receives a result of the comparison from the LSI tester through the interface circuit and compares the received comparison result with the expected value described in the event-driven test bench to determine whether the semiconductor device is a defective or a non-defective;
at least one or more external devices are connected to the semiconductor device;
the calculator includes at least one or more virtual devices which have to operate in conjunction with the semiconductor device; and
the calculator determines whether the semiconductor device is a defective or a non-defective at the time of a system operation in which the semiconductor device and the external devices operate in conjunction with each other, and determines whether the semiconductor device is a defective or a non-defective at the time of a system operation in which the semiconductor device and the virtual devices operate in conjunction with each other.

18. A semiconductor tester comprising:
a calculator in which an event-driven test bench, in which pieces of information on input timing, output timing, an input, and an expected value are described, and a voltage condition table, in which a power supply voltage and an input voltage are described, are recoded; and
an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table,
wherein the calculator receives a result of the comparison from the LSI tester through the interface circuit and compares the received comparison result with the expected value described in the event-driven test bench to determine whether the semiconductor device is a defective or a non-defective;
the event-driven test bench is a VCD (Verilog Value Change Dump), which is output as a result of a logic simulation performed using the event-driven test bench;
at least one or more external devices are connected to the semiconductor device; and
the calculator determines whether the semiconductor device is a defective or a non-defective at the time of a system operation in which the semiconductor device and the external devices operate in conjunction with each other.

19. A semiconductor tester comprising:
a calculator in which an event-driven test bench, in which pieces of information on input timing, output timing, an input, and an expected value are described, and a voltage condition table, in which a power supply voltage and an input voltage are described, are recoded; and
an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table,
wherein the calculator receives a result of the comparison from the LSI tester through the interface circuit and compares the received comparison result with the expected value described in the event-driven test bench to determine whether the semiconductor device is a defective or a non-defective;
the event-driven test bench is a VCD (Verilog Value Change Dump), which is output as a result of a logic simulation performed using the event-driven test bench;
the calculator includes at least one or more virtual devices which have to operate in conjunction with the semiconductor device; and
the calculator determines whether the semiconductor device is a defective or a non-defective at the time of a system operation in which the semiconductor device and the virtual devices operate in conjunction with each other.

20. A semiconductor tester comprising:
a calculator in which an event-driven test bench, in which pieces of information on input timing, output timing, an input, and an expected value are described, and a voltage condition table, in which a power supply voltage and an input voltage are described, are recoded; and
an LSI tester, connected to the calculator through an interface circuit, for applying an input signal, which is obtained from the event-driven test bench and the voltage condition table, to a semiconductor device to be tested, receiving an output signal produced from the semiconductor device in response to the applied input signal, and comparing the output signal with an output signal, which is obtained from the event-driven test bench and the voltage condition table,
wherein the calculator receives a result of the comparison from the LSI tester through the interface circuit and compares the received comparison result with the expected value described in the event-driven test bench to determine whether the semiconductor device is a defective or a non-defective;
the event-driven test bench is a VCD (Verilog Value Change Dump), which is output as a result of a logic simulation performed using the event-driven test bench;
at least one or more external devices are connected to the semiconductor device;
the calculator includes at least one or more virtual devices which have to operate in conjunction with the semiconductor device; and
the calculator determines whether the semiconductor device is a defective or a non-defective at the time of a system operation in which the semiconductor device and the external devices operate in conjunction with each other, and determines whether the semiconductor device is a defective or a non-defective at the time of a system operation in which the semiconductor device and the virtual devices operate in conjunction with each other.

21. The semiconductor tester of claim 15, wherein the calculator compares a result of a unit test or a system test on a defective semiconductor device in which a failure occurs with a result of a unit test or a system test on a non-defective semiconductor device in which no failure occurs, thereby specifying the location of the failure in the defective semiconductor device in accordance with information on the comparison.

22. The semiconductor tester of claim 15, wherein the calculator compares a result of a unit test or a system test on a defective semiconductor device in which a failure occurs with a result of a unit test or a system test on design data for a semiconductor device in which no failure occurs, thereby specifying the location of the failure in the defective semiconductor device in accordance with information on the comparison, the design data being recorded in the calculator.

23. The semiconductor tester of claim 21, wherein the calculator conducts a unit test or a system test on the defective semiconductor device, in which the location of the failure has been specified, and a unit test or a system test on design data for this semiconductor device, which is design data recorded in the calculator and reflecting failure information about the specified failure location, and compares results of the tests with each other to determine whether or not the failure information about the defective semiconductor device is correct.

24. The semiconductor tester of claim 22, wherein the calculator conducts a unit test or a system test on the defective semiconductor device, in which the location of the failure has been specified, and a unit test or a system test on design data for this semiconductor device, which is design data recorded in the calculator and reflecting failure information about the specified failure location, and compares results of the tests with each other to determine whether or not the failure information about the defective semiconductor device is correct.

25. The semiconductor tester of claim 15, wherein the calculator conducts a unit test or a system test on a semiconductor device processed by a focused ion beam system, and a unit test or a system test on a semiconductor device which is not processed by the focused ion beam system, and compares results of the tests with each other to determine whether or not the processing performed on the semiconductor device is successful processing.

26. The semiconductor tester of claim 15, wherein a unit test or a system test is conducted on a semiconductor device processed by a focused ion beam system, and a unit test or a system test is conducted on design data for this semiconductor device, and results of the tests are compared with each other to determine whether or not the processing performed on the semiconductor device is successful processing, the design data being recorded in the calculator.
